(19) United States
(12) Patent Application Publication
(10) Pub. No.: US 2026/0060090 A1
(43) Pub. Date: Feb. 26, 2026

(54) IMAGE SENSOR

(71) Applicant: Samsung Electronics Co., Ltd., Suwon-si (KR)

(72) Inventors: Doyeon KIM, Suwon-si (KR); Daehoon KIM, Suwon-si (KR); Jongeun PARK, Suwon-si (KR); Junha KANG, Suwon-si (KR); In Ho RO, Suwon-si (KR)

(73) Assignee: Samsung Electronics Co., Ltd., Suwon-si (KR)

(21) Appl. No.: 19/301,447

(22) Filed: Aug. 15, 2025

(30) Foreign Application Priority Data
Aug. 21, 2024 (KR) 10-2024-0111987

(51) Int. Cl. H01L 23/60; H01L 23/00; H10F 39/00

(52) U.S. Cl. CPC H01L 23/60; H01L 24/08; H10F 39/809; H10F 39/811; H01L 2224/08145; H01L 2924/30205

(57) ABSTRACT

An image sensor includes a first substrate having a first surface and a second surface opposite to the first surface, and including a plurality of pixel region groups, each of the pixel region groups including a plurality of pixel regions, the pixel regions oriented in a first and second directions parallel to the first surface, the second direction intersecting the first direction; first bonding pads on the first surface and the pixel region groups; first shield conductive patterns on the first surface, on each of boundaries of the pixel region groups parallel to the first direction, and oriented in matrix form along the first direction and second direction, columns of the matrix apart from each other; and a first pickup region in at least one of the pixel regions, wherein each of the first shield conductive patterns is electrically connected to the first pickup region in a corresponding pixel region.

### CROSS-REFERENCE TO RELATED APPLICATION(S)

This U.S. non-provisional application claims priority under 35 USC § 119 to Korean Patent Application No. 10-2024-0111987, filed on Aug. 21, 2024, in the Korean Intellectual Property Office, the disclosure of which is herein incorporated by reference in its entirety.

### BACKGROUND

Inventive concepts relate to an image sensor and/or to methods of manufacturing the same.

An image sensor may be or include a semiconductor element that converts an optical image into an electrical signal. Recently, with the development of the computer industry and the communication industry, demand for image sensors with improved performance has increased in various fields such as, for example, digital cameras, camcorders, Personal Communication System (PCS), gaming devices, security cameras, and medical micro cameras. Image sensors may be classified into, for example, charge coupled device (CCD) type and complementary metal oxide semiconductor (CMOS) type. The CMOS type image sensor may be provided with a plurality of pixels arranged two-dimensionally. Each of the pixels may include a photodiode (PD). The photodiode may serve to convert incident light into an electrical signal.

### SUMMARY

At least some example embodiments relate to an image sensor including shield conductive patterns that are spaced apart from each other and have short line patterns.

An image sensor may include a first substrate having a first surface and a second surface opposite to the first surface, the first substrate including a plurality of pixel region groups, each of the pixel region groups including a plurality of pixel regions, the pixel regions being oriented in a first direction and a second direction intersecting the first direction, the first and second directions being parallel to the first surface; first bonding pads on the first surface of the first substrate and individually on each of the pixel region groups; first shield conductive patterns on the first surface of the first substrate, the first shield conductive patterns being individually on each of boundaries of the pixel region groups that are parallel to the first direction, the first shield conductive patterns being in matrix form along the first direction and second direction, the first shield conductive patterns of each column of the matrix being spaced apart from each other; and a first pickup region in at least one of the pixel regions of each of the pixel region groups, wherein each first shield conductive pattern is electrically connected to one of the first pickup regions that is in a corresponding pixel region of the pixel region groups.

An image sensor may include a first substrate having a first surface and a second surface opposite to the first surface, the first substrate including a plurality of pixel region groups, each of the pixel region groups including a plurality of pixel regions, the pixel regions being oriented in a first direction and a second direction intersecting the first direction, the first and second directions being parallel to the first surface; first bonding pads on the first surface of the first substrate and individually on each of the pixel region groups; first shield conductive patterns on the first surface of the first substrate, the first shield conductive patterns being individually on each of boundaries of the pixel region groups that are parallel to the first direction, the first shield conductive patterns being in matrix form along the first direction and second direction, the first shield conductive patterns of each column of the matrix being spaced apart from each other; a first pickup region in at least one of the pixel regions of each of the pixel region groups, a second substrate having a third surface and a fourth surface, the third surface facing the first surface, the fourth surface opposite to the third surface; second bonding pads on the third surface of the second substrate; second shield conductive patterns on the third surface of the second substrate, the second shield conductive patterns being individually bonded to each of the first shield conductive patterns; and second pickup regions in the second substrate, wherein each of the first shield conductive patterns is electrically connected to one of the first pickup regions that is in a corresponding pixel region of the pixel region groups, and each of the second shield conductive patterns is electrically connected to a corresponding pickup region of the second pickup regions. Each of the first and the second shield conductive patterns may have a bar shape extending in the first direction.

### BRIEF DESCRIPTION OF DRAWINGS

FIG. 1 is a block diagram of an image sensor according to some example embodiments.

FIG. 2 is a circuit diagram of a pixel array of an image sensor according to some example embodiments.

FIGS. 3A and 3B are circuit diagrams of pixel groups of image sensors according to some example embodiments.

FIG. 4 is a plan view of an image sensor according to some example embodiments.

FIG. 5 is a plan view of an image sensor according to some example embodiments.

FIGS. 6 to 8 show image sensors according to some example embodiments, which are enlarged cross-sectional views corresponding to portion ‘PXRG’ of FIG. 4.

FIG. 9 is a cross-sectional view corresponding to line I-I′ of FIG. 6.

FIG. 10 is a cross-sectional view corresponding to line II-II′ of FIG. 6.

FIG. 11 is a cross-sectional view corresponding to line III-III′ of FIG. 6.

FIG. 12 is a cross-sectional view corresponding to line IV-IV′ of FIG. 6.

FIG. 13 shows an image sensor according to some example embodiments, which is a cross-sectional view corresponding to line II-II′ of FIG. 8,

FIG. 14 is a cross-sectional view of an image sensor according to some example embodiments.

FIG. 15 is a plan view of the image sensor according to some example embodiments.

FIG. 16 is a cross-sectional view corresponding to line I-I′ of FIG. 15.

### DETAILED DESCRIPTION

Hereinafter, some example embodiments of inventive concepts are described in detail with reference to the accompanying drawings.

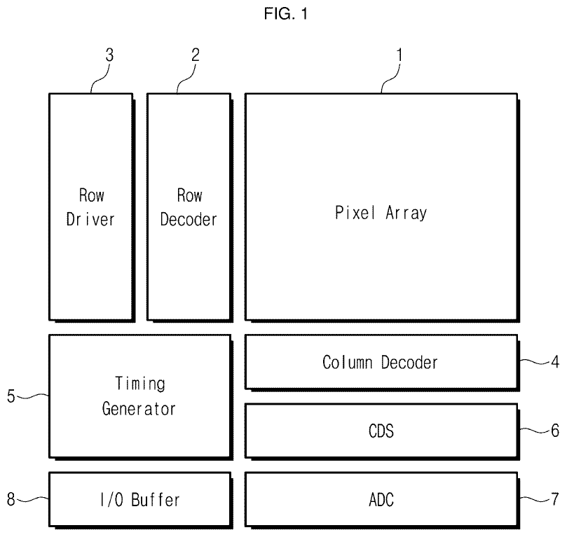

FIG. 1 is a block diagram of an image sensor according to some example embodiments.

Referring to FIG. 1, the image sensor according to some example embodiments may include a pixel array 1, a row decoder 2, a row driver 3, a column decoder 4, a timing generator 5, a correlated double sampler (CDS) 6, an analog to digital converter (ADC) 7, and an input/output buffer (I/O buffer) 8.

The pixel array 1 may include a plurality of pixels arranged two-dimensionally. According to some example embodiments, some of the pixels may form a pixel group, and the plurality of pixel groups may be arranged two-dimensionally in the pixel array 1. The pixels may convert optical signals into electrical signals. The pixel array 1 may be driven by a plurality of driving signals (e.g., a pixel selection signal, a reset signal, and/or a charge transfer signal) transmitted from the row driver 3. The converted electrical signals may be provided to the correlated double sampler 6.

The row driver 3 may provide the pixel array 1 with a plurality of driving signals for driving the plurality of pixels based on the result of decoding in the row decoder 2. When the pixels are arranged in a matrix form, the driving signals may be provided in a row unit.

The timing generator 5 may provide timing signals and control signals to the row decoder 2 and the column decoder 4.

The correlated double sampler 6 may receive the electrical signals generated from the pixel array 1 and may hold and sample the received signals. The correlated double sampler 6 may double sample a specific noise level and a signal level caused by an electrical signal to output a difference level corresponding to the difference between the noise level and the signal level.

The analog to digital converter 7 may convert an analog signal corresponding to the difference level output from the correlated double sampler 6 into a digital signal and may output the digital signal.

The input/output buffer 8 may latch the digital signals and sequentially output the latched signals to an image signal processor (not shown) based on the result of decoding in the column decoder 4.

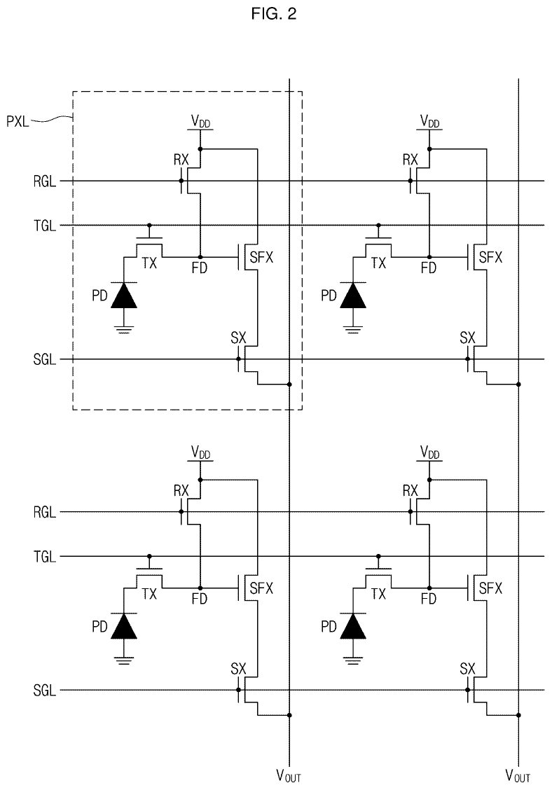

FIG. 2 is a circuit diagram of the pixels included in the pixel array of the image sensor according to some example embodiments.

Referring to FIG. 2, the pixel array may include a plurality of pixels PXL, and the pixels PXL may be arranged in a matrix form. Each of the pixels PXL may include a transfer transistor TX and logic transistors CX, SX, and SFX. The logic transistors CX, SX, and SFX may include a control transistor CX, a selection transistor SX, and a source follower transistor SFX. A transfer gate of the transfer transistor TX may be connected to a transfer gate line TGL. Each of the pixels PXL may, for example, further include a photodiode PD and a floating diffusion region FD.

The photodiode PD may generate and accumulate photocharges in proportion to the amount of light incident from the outside. The photodiode PD may include, for example, a photoelectric conversion elemente, a phototransistor, a photogate, a pinned photodiode, or a combination thereof. The transfer transistor TX may transfer the photocharges generated from the photodiode PD to the floating diffusion region FD. The floating diffusion region FD may receive and cumulatively store the photocharges generated from the photodiode PD.

A gate of the source follower transistor SFX may be connected to the floating diffusion region FD. One source/drain electrode of the source follower transistor SFX may be connected to a power voltage node VDD. The source follower transistor SFX may be controlled according to the amount of photocharges accumulated in the floating diffusion region FD.

The control transistor CX may serve as a reset transistor to periodically reset the photocharges accumulated in the floating diffusion region FD. A gate of the control transistor CX may be connected to a reset gate line RGL. Each of source/drain electrodes of the control transistor CX may be connected to each of the floating diffusion region FD and the power voltage node VDD (for example, the source/drain electrodes of the control transistor CX may be individually or respectively connected to each of the floating diffusions FD and the power voltage node VDD). For example, a power source/drain electrode of the control transistor CX may be connected to the power voltage node VDD, and a control source/drain electrode of the control transistor CX may be connected to the floating diffusion region FD. When the control transistor CX is turned on, the charges accumulated in the floating diffusion region FD may be discharged by the power voltage of the power voltage node VDD, thereby resetting the floating diffusion region FD.

The source follower transistor SFX may serve as a source follower buffer amplifier. The source follower transistor SFX may amplify a change in potential in the floating diffusion region FD and output the change in amplified potential to an output line VOUT.

A gate of the selection transistor SX may be connected to a selection gate line SGL. Each of source/drain electrodes of the selection transistor SX may be connected to each of the other source/drain electrodes of the source follower transistor SFX and the output line VOUT. The selection transistors SX of the pixels PXL to be read in a row unit may be selected by a selection signal applied through a corresponding selection gate line SGL. When the selection transistor SX is turned on, the change in potential amplified by the source follower transistor SFX may be output to the output line VOUT through the selection transistor SX.

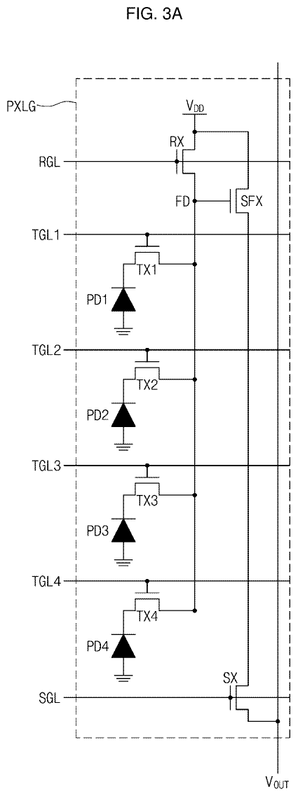

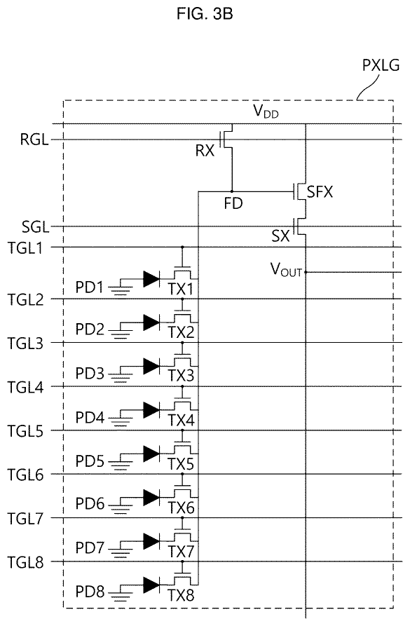

FIGS. 3A and 3B are circuit diagrams of pixel groups of image sensors according to some example embodiments.

Referring to FIGS. 3A and 3B, the pixel array may include pixel groups PXLG, and each of the pixel groups PXLG may include a plurality of pixels. A circuit diagram of a single pixel group PXLG is shown in each of FIGS. 3A and 3B.

Referring to FIG. 3A, in some example embodiments, the pixel group PXLG may include four pixels (for example, first to fourth pixels). The first pixel may include a first transfer transistor TX1 and a first photodiode PD1, the second pixel may include a second transfer transistor TX2 and a second photodiode PD2, the third pixel may include a third transfer transistor TX3 and a third photodiode PD3, and the fourth pixel may include a fourth transfer transistor TX4 and a fourth photodiode PD4. Gates of the first to fourth transfer transistors TX1 to TX4 may be connected to first to fourth transfer gate lines TGL1 to TGL4, respectively. In some example embodiments, the first to fourth pixels of the pixel group PXLG may share the reset transistor RX, the source follower transistor SFX, and the selection transistor SX previously described.

Referring to FIG. 3B, in some example embodiments, the pixel group PXLG may include, for example, eight pixels. First to eighth pixels may include first to eighth transfer transistors TX1 to TX8 and first to eighth photodiodes PD1 to PD8, respectively. Gates of the first to eighth transfer transistors TX1 to TX8 may be connected to first to eighth transfer gate lines TGL1 to TGL8, respectively. In some example embodiments, the first to eighth pixels may share the reset transistor RX, the source follower transistor SFX, and the selection transistor SX previously described.

In example embodiments relating to FIGS. 3A and 3B, the pixel group PXLG may include, for example, the four pixels or the eight pixels. However, example embodiments of inventive concepts are not limited thereto, and the number of pixels in the pixel group PXLG may be variously changed.

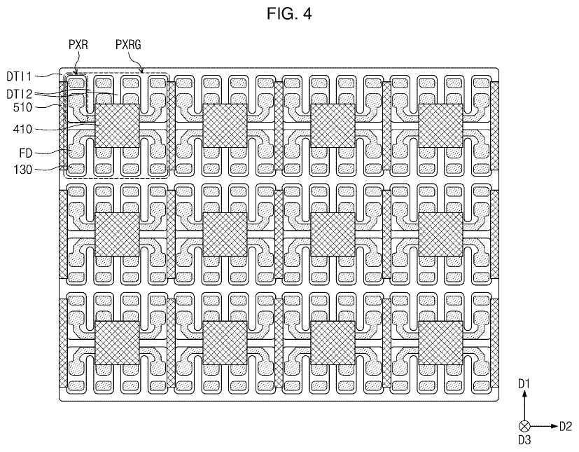

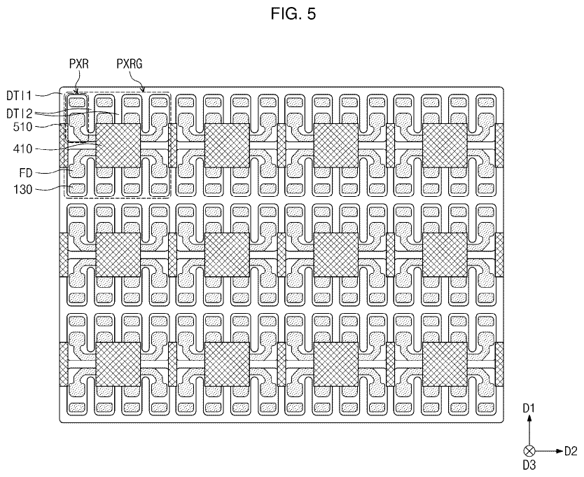

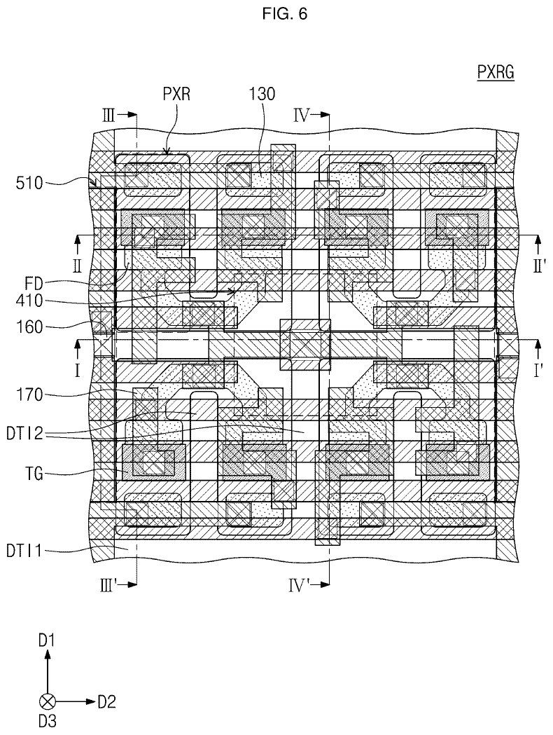

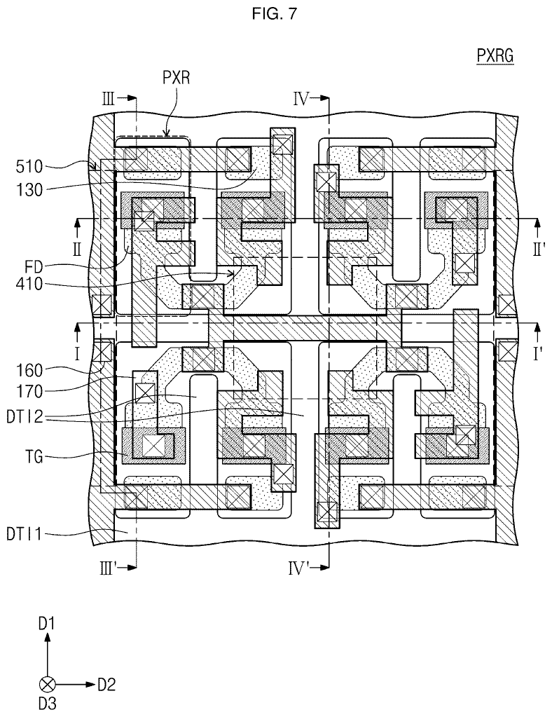

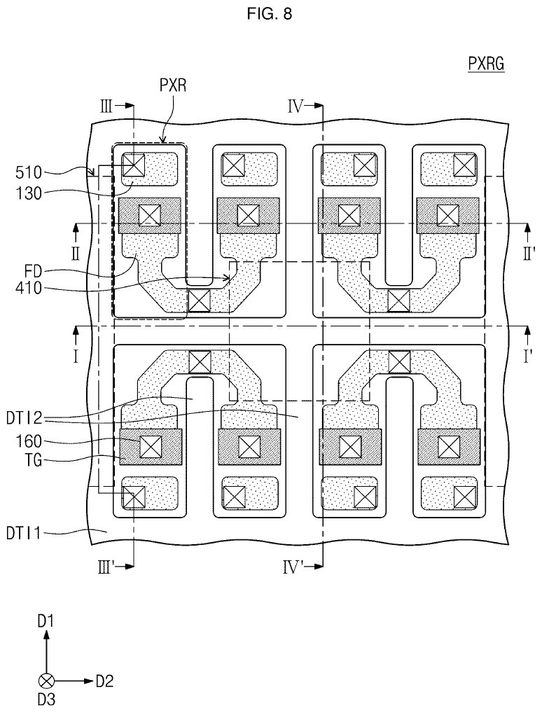

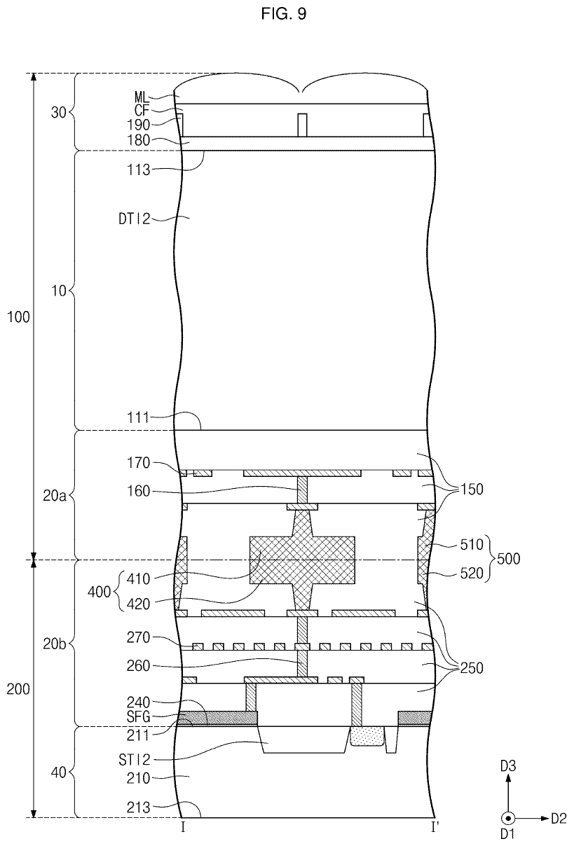

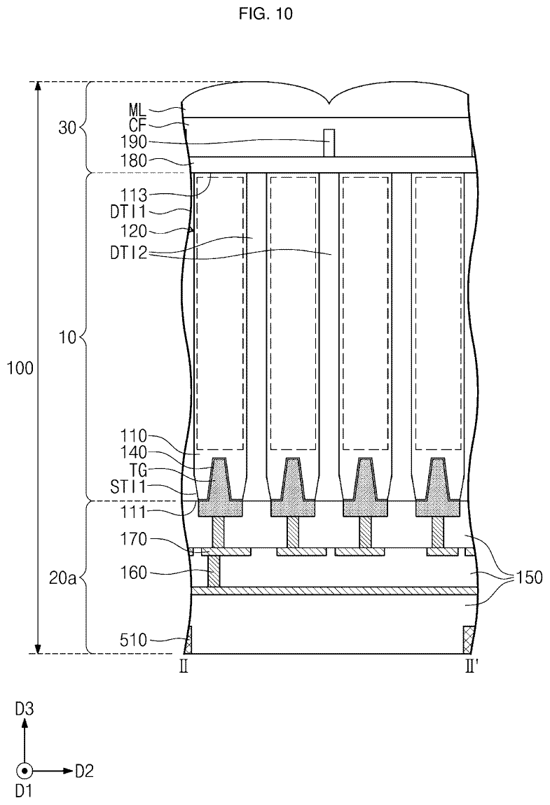

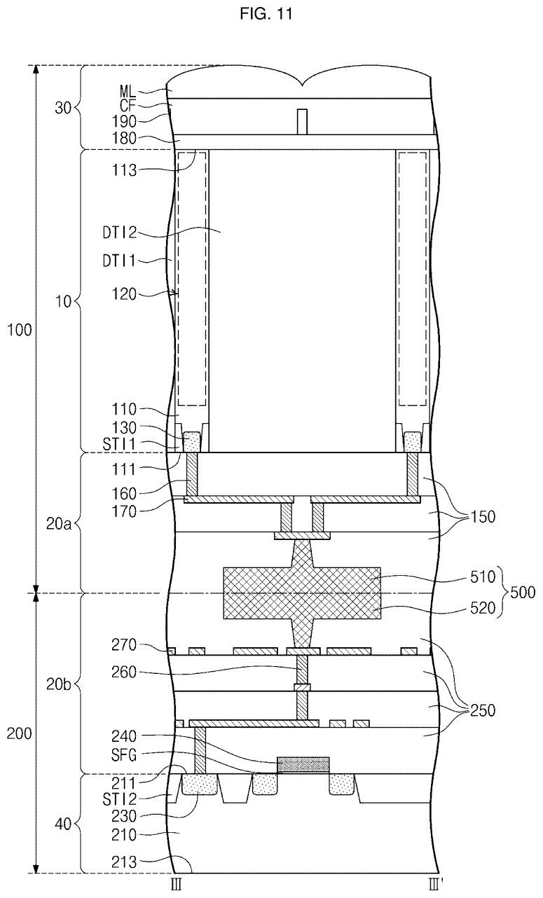

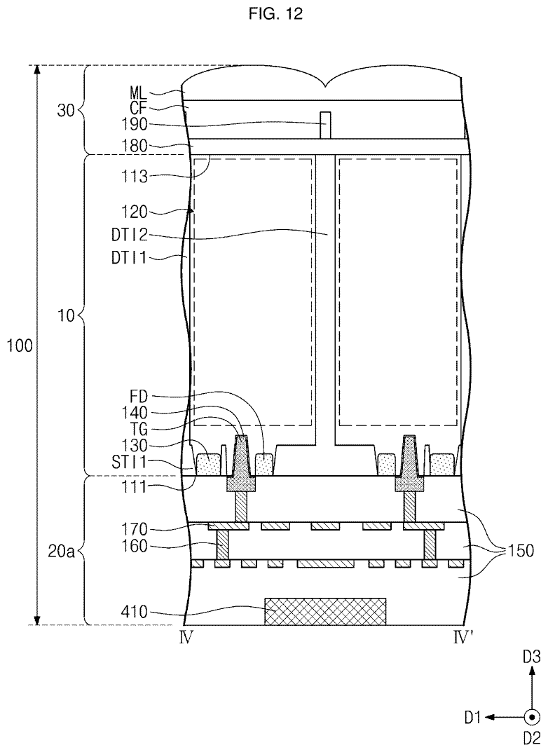

FIG. 4 is a plan view of the image sensor according to some example embodiments. FIG. 5 is a plan view of the image sensor according to some example embodiments. FIGS. 6 to 8 show image sensors according to some example embodiments, which are enlarged cross-sectional views corresponding to portion ‘PXRG’ of FIG. 4. Specifically, for convenience of explanation and illustration, some components have been omitted in FIGS. 6 to 8. For example, shield conductive patterns and bonding pads have been omitted in FIG. 6, the shield conductive patterns, the bonding pads, and some of wiring layers have been omitted in FIG. 7, and the shield conductive patterns, the bonding pads, and the wiring layers have been omitted in FIG. 8. FIG. 9 is a cross-sectional view corresponding to line I-I′ of FIG. 6. FIG. 10 is a cross-sectional view corresponding to line II-II′ of FIG. 6. FIG. 11 is a cross-sectional view corresponding to line III-III′ of FIG. 6. FIG. 12 is a cross-sectional view corresponding to line IV-IV′ of FIG. 6.

Referring to FIGS. 4 and 6 to 12, an image sensor according to some example embodiments may include a photoelectric conversion structure 100. The photoelectric conversion structure 100 may be referred to as a first structure 100 and may include a photoelectric conversion layer 10, a first wiring layer 20a, and a light control layer 30. An intermediate structure 200 may be referred to as a second structure 200 and may include a second wiring layer 20b and an intermediate layer 40. The first structure 100 may be stacked on the second structure 200.

The photoelectric conversion layer 10 may be disposed between the first wiring layer 20a and the light control layer 30, and may include a first substrate 110, a photodiode 120, a first deep element isolation pattern DTI1, a second deep element isolation pattern DTI2, a first shallow element isolation pattern STI1, a floating diffusion region FD, a transfer gate TG, a first pickup region 130, and a gate insulating film 140.

The first substrate 110 may have a first surface 111 and a second surface 113 opposite to the first surface 111. The first surface 111 may be a front surface of the first substrate 110, and the second surface 113 may be a back surface of the first substrate 110. Light may be incident on the second surface 113 of the first substrate 110. In other words, the second surface 113 of the first substrate 110 may be a light incident surface.

The first substrate 110 may be, for example, a silicon (Si) substrate, a germanium (Ge) substrate, a silicon-germanium (Si—Ge) substrate, a group II-VI compound semiconductor substrate, a group III-V compound semiconductor substrate, or a silicon on insulator (SOI) substrate, but example embodiments are not limited thereto. The first substrate 110 may include impurities of a first conductivity type, and accordingly, the first substrate 110 may have the first conductivity type. For example, the impurities of the first conductivity type may be a group III element. For example, the impurities of the first conductivity type may include P-type impurities such as, for example, aluminum (Al), boron (B), indium (In), and/or gallium (Ga).

The photodiode 120 may be provided in the first substrate 110. In some example embodiments, the photodiode 120 may include impurities having a second conductivity type different from the first conductivity type, and accordingly, the photodiode 120 may have the second conductivity type. For example, the impurities of the second conductivity type may be or include a group V element. For example, the impurities of the second conductivity type may include N-type impurities such as, for example, phosphorus, arsenic, bismuth, and/or antimony.

The first substrate 110 and the photodiode 120 may form the above-described photodiode PD by being P-N junctioned with each other.

In some example embodiments, the first deep element isolation pattern DTI1 is provided in the first substrate 110 to define pixel region groups PXRG in the first substrate 110. In some example embodiments, the first deep element isolation pattern DTI1 may pass through the first substrate 110. For example, the first deep element isolation pattern DTI1 may pass through the first and second surfaces 111 and 113 of the first substrate 110 and a body of the substrate between the first and second surfaces 111 and 113 of the first substrate 110.

In some example embodiments, the first deep element isolation pattern DTI1 may be formed in the first substrate 110 to surround each of the pixel region groups PXRG in a plan view. For example, the first deep element isolation pattern DTI1 may be formed by a technique (for example, by a deep trench isolation (DTI) technique) of filling a deep trench formed by being patterned in the first substrate 110 with an insulating material. In some example embodiments, the pixel region groups PXRG may be arranged two-dimensionally.

Each of the pixel region groups PXRG may have at least two pixel regions PXR. In some example embodiments, the at least two pixel regions PXR may be separated by at least one of various isolation techniques. For example, the at least two pixel regions PXR may be separated from each other by a doping isolation technique. For example, a doped isolation region may be provided between the at least two pixel regions PXR. Alternatively, the at least two pixel regions PXR may be separated from each other by the second deep element isolation pattern DTI2. In other words, the second deep element isolation pattern DTI2 may be formed in the first substrate 110 between the at least two pixel regions PXR. Alternatively, the doped isolation region and the second deep element isolation pattern DTI2 may be formed in the first substrate 110 between the at least two pixel regions PXR.

In other words, each of the pixel regions PXR may be defined by the first and second deep element isolation patterns DTI1 and DTI2. According to some example embodiments, each of the pixel regions PXR may be or be included in a portion of the first substrate 110 surrounded or at least partially surrounded by the first and second deep element isolation patterns DTI1 and DTI2 in a plan view. The pixel regions PXR of the pixel region groups PXRG may be arranged in a matrix form along first and second directions D1 and D2. In some example embodiments, the first and second directions D1 and D2 may be parallel to the first surface 111 of the first substrate 110 and may intersect each other. For example, the first and second directions D1 and D2 may be perpendicular to each other. The first and second deep element isolation patterns DTI1 and DTI2 may extend in a direction (for example, a third direction D3) perpendicular to the first surface 111 of the first substrate 110.

The first shallow element isolation pattern STI1 may be provided in the first substrate 110 to define active regions. The first shallow element isolation pattern STI1 may be adjacent to the first surface 111 of the first substrate 110. The first shallow element isolation pattern STI1 may be provided between the active regions to electrically isolate the active regions from each other. In some example embodiments, the first shallow element isolation pattern STI1 may define at least one active region in each of the pixel regions.

In some example embodiments, the first deep element isolation pattern DTI1 may overlap or at least partially overlap the first shallow element isolation pattern STI1. For example, the first deep element isolation pattern DTI1 may pass through a portion of the first shallow element isolation pattern STI1. The overlapping portion of the first deep element isolation pattern DTI1 and the first shallow element isolation pattern STI1 may correspond to a portion of the first shallow element isolation pattern STI1 or a portion of the first deep element isolation pattern DTI1.

The transfer gate TG may be disposed on the first surface 111 of the first substrate 110. The transfer gate TG may be disposed on the corresponding active region (hereinafter, referred to as a first active region) of each of the pixel regions. The gate insulating film 140 may be disposed between the transfer gate TG and the first active region.

The floating diffusion region FD may be provided in the first active region at one side of the transfer gate TG. In some example embodiments, the floating diffusion region FD may be, for example, a region doped with impurities having the second conductivity type.

As shown in FIGS. 4 to 9, each of the floating diffusion regions FD provided in each of two neighboring pixel regions PXR may be connected to each other to form a single floating diffusion region FD.

The first pickup region 130 may be provided in a second active region spaced apart from the first active region. In some example embodiments, the first pickup region 130 may be, for example, a region doped with the impurities of the second conductivity type.

In some example embodiments, a gate spacer (not shown) may be provided on side surfaces of the transfer gate TG. The gate spacer may, for example, include an insulating material different from that of the first shallow element isolation pattern STI1. For example, when the first shallow element isolation pattern STI1 includes silicon oxide, the gate spacer may include silicon nitride and/or silicon oxynitride, but example embodiments are not limited thereto.

The first wiring layer 20a may include first interlayer insulating films 150, first contact plugs 160, first wirings 170, a first bonding pad 410, and first shield conductive patterns 510.

The first interlayer insulating films 150 may be provided on the first surface 111 of the first substrate 110. The first interlayer insulating films 150 may cover the first surface 111, the floating diffusion regions FD, and the transfer gates. For example, each of the first interlayer insulating films 150 may include at least one of silicon oxide, silicon oxynitride, and silicon nitride, but example embodiments are not limited thereto. In some example embodiments, the first interlayer insulating films 150 may be sequentially stacked on the first surface 111 of the first substrate 110. The first contact plugs 160 and the first wirings 170 may be provided in the first interlayer insulating films 150.

The first bonding pad 410 may be provided on the first surface 111 of the first substrate 110 and may be provided on any or each of the pixel region groups PXRG. In some example embodiments, the first bonding pad 410 may be disposed in and/or at a level of the lowermost layer among (for example, lowermost of) the first interlayer insulating films 150, but example embodiments are not limited thereto.

In some example embodiments, each of the first bonding pads 410 may be electrically connected to one of the floating diffusion regions FD that is provided in the corresponding one among the pixel region groups PXRG. In some example embodiments, the first bonding pad 410 may include, for example, copper, but example embodiments are not limited thereto.

Each of the first shield conductive patterns 510 may be provided on the first surface 111 of the first substrate 110 and may be provided on (for example, the first shield conductive patterns 510 may be individually or respectively on) each of boundaries of the pixel region groups PXRG that are parallel to the first direction D1. In some example embodiments, the first shield conductive patterns 510 may be positioned within and/or at a level of the lowermost layer among (for example, a lowermost of) the first interlayer insulating films 150.

The first shield conductive patterns 510 may be arranged (for example, oriented) in a matrix form along the first and second directions D1 and D2. In some example embodiments, the first shield conductive patterns 510 forming (for example, of) each column of the matrix form may be spaced apart from each other. For example, the first shield conductive patterns 510 may be physically spaced apart from each other.

In some example embodiments, each of the first shield conductive patterns 510 may be electrically connected to a first pickup region 130 provided in a corresponding one of the pixel region groups PXRG. Moreover, each of the first shield conductive patterns 510 may have a bar shape extending in the first direction D1. As shown in FIGS. 4 and 5, a length of each of the first shield conductive patterns 510 in the first direction D1 may be larger (e.g., greater) than or equal to a width of each of the first bonding pads 410 in the first direction D1. In some example embodiments, the first shield conductive patterns 510 may not be provided on the boundaries of the pixel region groups PXRG that are parallel to the second direction D2.

Referring to FIGS. 6 to 9, for example, in some example embodiments, each of the pixel region groups PXRG may include eight pixel regions PXR, and a first pickup region 130 and transfer gate TG may be provided in and/or on each of the pixel regions PXR. However, example embodiments are not limited thereto. In some example embodiments, the number of pixel regions PXR in the pixel region groups PXRG may be variously changed (e.g., may differ). In some example embodiments, the first pickup region 130 may be provided in at least one of the pixel regions PXR in the pixel region group PXRG.

In some example embodiments, the first bonding pad 410 may be electrically connected to the floating diffusion regions FD that are in each of the pixel region groups PXRG through corresponding one(s) of the first wirings 170 and the corresponding one(s) of the first contact plugs 160. Similarly, each of the first shield conductive patterns 510 may be electrically connected to first pickup region(s) 130 in corresponding pixel region group PXRG through (for example, by) corresponding one(s) of the first wirings 170 and corresponding one(s) of the first contact plugs 160.

The intermediate layer 40 may include a second substrate 210, a second shallow element isolation pattern STI2, a second pickup region 230, gates, and a second gate insulating film 240. The second wiring layer 20b may include second interlayer insulating films 250, second contact plugs 260, second wirings 270, a second bonding pad 420, and second shield conductive patterns 520.

The second substrate 210 may have a third surface 211 facing the first surface 111 of the first substrate 110 and a fourth surface 213 opposite to the third surface 211.

The second shallow element isolation pattern STI2 may be disposed in a shallow trench recessed by a specific depth from (for example, with respect to) the third surface 211 of the second substrate 210. In other words, the second shallow element isolation pattern STI2 may be adjacent to the third surface 211 of the second substrate 210. In some example embodiments, the second shallow element isolation pattern STI2 may define the active regions (e.g., a third active region, a fourth active region, etc.) in the second substrate 210.

The gates (e.g., a reset gate, a selection gate, a source follower gate SFG, etc.) may be disposed on the corresponding third active regions of the second substrate 210. In some example embodiments, the reset gate (not shown), the selection gate (not shown), and the source follower gate SFG may be disposed on the third surface 211 of the second substrate 210. The second gate insulating film 240 may be disposed between the third active regions corresponding to each of the reset gate, the selection gate, and the source follower gate SFG. Source/drain regions may be disposed in the corresponding third active regions at both sides of each of the gates.

The second pickup region 230 may be provided in the fourth active region spaced apart from the third active region. In some example embodiments, the second pickup region 230 may be a region doped with the impurities of the second conductivity type. In some example embodiments, a plurality of fourth active regions may be defined in the second substrate 210, and each of a plurality of second pickup regions 230 may be provided in each of the plurality of fourth active regions (e.g., a second pickup region 230 may be in each fourth active region). Each of the plurality of second pickup regions 230 may correspond to each of (for example, one of) a plurality of second shield conductive patterns 520.

The second wiring layer 20b may include the second interlayer insulating films 250, the second contact plugs 260, the second wirings 270, the second bonding pads 420, and the second shield conductive patterns 520.

The second interlayer insulating films 250 may be provided on the third surface 211 of the second substrate 210. The second interlayer insulating films 250 may cover the third surface 211, the gates, and the second pickup region 230. In some example embodiments, each of the second interlayer insulating films 250 may include at least one of a silicon oxide, a silicon oxynitride, or a silicon nitride, but example embodiments are not limited thereto. In some example embodiments, the second interlayer insulating films 250 may be sequentially stacked on the third surface 211 of the second substrate 210. The second contact plugs 260 and the second wirings 270 may be provided in the second interlayer insulating films 250.

Each of the second bonding pad 420 may be provided on the third surface 211 of the second substrate 210 and may be provided on each of the pixel region groups PXRG (for example, each pixel region group PXRG may have a second bonding pad 420 thereon). In some example embodiments, the second bonding pad 420 may be disposed in the uppermost layer among the second interlayer insulating films 250.

In some example embodiments, each of the second bonding pads 420 may be electrically connected to the source follower gate SFG provided on the third surface 211 of the second substrate 210. In some example embodiments, the second bonding pad 420 may include copper.

The first and second bonding pads 410 and 420 may electrically connect the structures 100, 200. In other words, the floating diffusion region FD and the source follower gate SFG in the image sensor may be electrically connected. In such a case, the first and second bonding pads 410 and 420 may be bonded to each other by, for example, a copper-copper bonding technique. The bonded bonding pads 410 and 420 may, for example, form a single body without a boundary surface therebetween. In some example embodiments, the lowermost layer of (for example a lowermost of) the first interlayer insulating films 150 may be bonded to the uppermost layer of (for example, uppermost of) the second interlayer insulating films 250 through covalent bonding.

Each of the second shield conductive patterns 520 may be provided on the third surface 211 of the second substrate 210 and may be provided on each of the boundaries of the pixel region groups PXRG parallel to the first direction D1 (for example, each of boundaries of the pixel region groups PXRG that are parallel to the first direction D1 may have one of the second shield conductive patterns 520 thereon). In some example embodiments, the second shield conductive patterns 520 may be positioned in the uppermost layer of (for example, an uppermost of) the second interlayer insulating films 250.

The second shield conductive patterns 520 may be arranged in a matrix form along the first and second directions D1 and D2. In some example embodiments, the second shield conductive patterns 520 forming each column of the matrix form may be spaced apart from each other. For example, the second shield conductive patterns 520 may be physically spaced apart from each other.

In some example embodiments, each of the second shield conductive patterns 520 may be electrically connected to a second pickup region 230 provided in the second substrate 210. Moreover, each of the second shield conductive patterns 520 may have a bar shape extending in the first direction D1. For example,, a length of each of the second shield conductive patterns 520 in the first direction D1 may be larger (e.g., greater) than or equal to a width of each of the second bonding pads 420 in the first direction D1. In some example embodiments, the second shield conductive patterns 520 may not be provided on the boundaries of the pixel region groups PXRG parallel to the second direction D2.

In some example embodiments, each of the second shield conductive patterns 520 may be bonded to each of the first shield conductive patterns 510 (for example, the second shield pattern 520 may be individually bonded to each of the first shield conductive patterns 510).

The light control layer 30 may include a light transmitting film 180, a grid 190, a color filter CF, and microlenses ML.

The light transmitting film 180 may be provided on the second surface 113 of the first substrate 110. The light transmitting film 180 may cover the second surface 113 of the first substrate 110 and upper surfaces of the first and second deep element isolation patterns DTI1 and DTI2. The light transmitting film 180 may include a transparent insulating material.

The grid 190 may be provided on the second surface 113 of the first substrate 110 with the light transmitting film 180 interposed therebetween. In other words, the grid 190 may be provided on the light transmitting film 180. The grid 180 may define openings. A color filter array including the color filters CF arranged two-dimensionally may be provided on the second surface 113 of the first substrate 110. The color filter array may be provided on the light transmitting film 180, and each of the color filters CF may fill the corresponding opening(s) among the openings of the grid 190. A lens array including the microlenses ML arranged two-dimensionally may be provided on the second surface 113 of the first substrate 110 with the color filter array interposed therebetween. For example, the color filter array may be disposed between the lens array and the light transmitting film 180.

In some example embodiments, each of the color filters CF may cover or at least partially cover the corresponding pixel regions among the pixel regions. For example, each of the color filters CF may be disposed on two pixel regions PXR arranged in a 1×2 matrix form in a plan view. In other words, each of the color filters CF may cover or at least partially cover a pair of pixel regions PXR adjacent to each other. However, example embodiments are not limited thereto. For example, each of the color filters CF may be disposed on four pixel regions PXR arranged in a 2×2 matrix form in a plan view. In addition, as shown in FIGS. 4 and 5, each of the color filters CF may be disposed on eight pixel regions PXR arranged in a 2×4 matrix form, on nine pixel regions PXR arranged in a 3×3 matrix form, or on sixteen pixel regions PXR arranged in a 4×4 matrix form.

In some example embodiments, the color filters CF may include a first color filter having a first color, a second color filter having a second color, and a third color filter having a third color. For example, each of the color filters CF may have any one color among red, green, or blue colors. Alternatively, each of the color filters CF may have any one color among cyan, magenta, or yellow colors. The color filters CF may also have other colors in addition to the previously described red, green, blue, cyan, magenta, or yellow color.

The grid 190 may guide incident light into the photodiode 120. The grid 190 may have a single-layer structure or a multi-layer structure. The grid 190 may include a metal-containing material (e.g., titanium, tungsten, aluminum, tantalum, etc.), a metal nitride (e.g., a titanium nitride, a tantalum nitride, etc.), and/or a low-refractive material, but example embodiments are not limited thereto. The low-refractive material may refer to a low refractive index material with a refractive index lower than that of silicon Si. In some example embodiments, the low-refractive material may include a metal oxide, and/or a polymer and silica nanoparticles in the polymer. For example, the low-refractive material may include at least one of a silicon oxide, an aluminum oxide, a tantalum oxide, or a silicon hydrogen oxynitride. In some example embodiments, the low-refractive material may have insulating properties.

In some example embodiments, the grid 190 may vertically overlap or at least partially overlap at least the first deep element isolation pattern DTI1. In some example embodiments, although not shown, the grid 190 may also vertically overlap or at least partially overlap the second deep element isolation pattern DTI2. However, example embodiments are not limited thereto. In some example embodiments, when the grid 190 is shifted laterally, at least a portion of the grid 190 may not vertically overlap the first and second deep element isolation patterns DTI1 and DTI2. For example, the grid 190 may have a structure offset laterally from the first and second deep element isolation patterns DTI1 and DTI2. The offset structure may be intentionally selected, for example to optimize or customize an optical path considering a margin of a manufacturing process and/or a traveling angle of incident light, etc.

The microlens ML may be disposed on the light transmitting film 180 with the color filter CF interposed therebetween. At least a portion of the microlens ML may vertically overlap or partially overlap the photodiode 120. The microlens ML may condense light incident toward the first substrate 110. In some example embodiments, the microlens ML may include an organic material such as, for example, a polymer. For example, the microlens ML may include a light-transmitting resin, a photoresist material, and/or a thermosetting resin, but example embodiments are not limited thereto.

In some example embodiments, the microlens ML may include a lens pattern and a planarized portion. The planarized portion may be provided on the color filter CF, and the lens pattern may be provided on the planarized portion. The lens pattern may include, for example, a same material as the planarized portion, but example embodiments are not limited thereto. The lens pattern and the planarized portion may form a single body without a boundary surface therebetween. In some example embodiments, the planarized portion may be omitted, and the lens pattern may be directly disposed on the color filter CF.

In some example embodiments, each of the microlenses ML may cover or at least partially each of the pixel regions. In other words, each of the microlenses ML may vertically overlap or at least partially overlap the corresponding one among the pixel regions. Accordingly, each of the microlenses ML may cover or at least partially cover a pair of sub-pixel regions included in the corresponding pixel region. Each of the microlenses ML may vertically overlap or at least partially overlap the pair of photodiodes 120 formed in the pair of sub-pixel regions. In some example embodiments, each of the microlenses ML in the lens array may vertically overlap or at least partially overlap the corresponding one among the pixel regions. Each of the microlenses ML may be provided to condense the incident light and may include a spherical lens, an aspherical lens, or a combination thereof. For example, each of the microlenses ML may have an upward convex shape in a cross-sectional view, but example embodiments are not limited thereto.

The image sensor in the above-described embodiments may include the first and second shield conductive patterns 510 and 520 that are spaced apart from each other and have short line shapes. When the long line shape is formed in the image sensor, a one or more micro voids may be formed in a portion or portions vulnerable to plasma induced damage (PID) related to the manufacturing process. A micro void may cause, for example, a white spot. However, according to example embodiments, the first and second shield conductive patterns 510 and 520 that are spaced apart from each other and have short line shapes may be provided in the image sensor. Accordingly, damage caused by plasma may be limited, minimized, or prevented. Moreover, the first and second shield conductive patterns 510 and 520 may be connected to the first and second pickup regions 130 and 230. Accordingly, even when charges are induced in the first and second shield conductive patterns 510 and 520 by plasma during the manufacturing process, the induced charges may be relatively smoothly discharged through the first and second pickup regions 130 and 230. Accordingly, damage to the first and second shield conductive patterns 510 and 520 may be limited, minimized, or prevented.

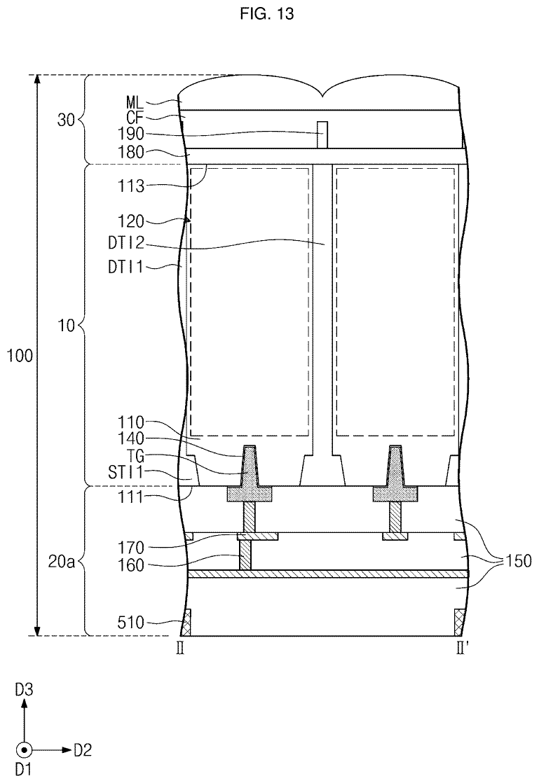

FIG. 13 shows an image sensor according to some example embodiments, which is a cross-sectional view corresponding to line II-II′ of FIG. 8. Hereinafter, for convenience of explanation, differences from the above-described embodiments will be mainly described.

Referring to FIG. 13, the image sensor in FIG. 8 includes eight pixel regions PXR arranged in a 2×4 matrix form, whereas the image sensor in FIG. 13 may include four pixel regions PXR arranged in a 2×2 matrix form. In other words, as described above, the number of pixel regions PXR in the pixel region group PXRG may be variously changed.

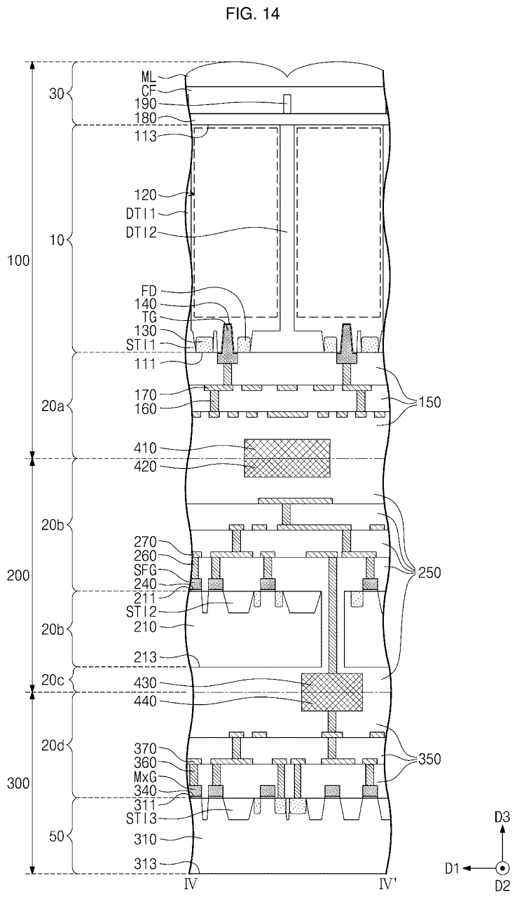

FIG. 14 is a cross-sectional view of an image sensor according to some example embodiments.

Referring to FIG. 14, the image sensor according to some example embodiments may include first to third structures 100, 200, and 300. The first structure 100 may be stacked on the second structure 200, and the second structure 200 may be stacked on the third structure 300. In other words, the second structure 200 may be disposed between the first structure 100 and the third structure 300. The third structure 300 may be referred to as a peripheral circuit structure or a third chip. The first structure 100 and the second structure 200 may be bonded to each other by at least one of various bonding methods and electrically connected to each other by at least one of various connection methods. Similarly, the second structure 200 and the third structure 300 may be bonded to each other by at least one of various bonding methods and electrically connected to each other by at least one of various connection methods.

The second structure 200 may further include a third wiring layer 20c, and the intermediate layer 40 may be disposed between the second wiring layer 20b and the third wiring layer 20c. The third wiring layer 30c may include the second interlayer insulating films 250 and a third bonding pad 430. The third bonding pad 430 may be disposed in the lowermost layer among the second interlayer insulating films 250.

The third structure 300 may include a peripheral circuit layer 50 and a fourth wiring layer 20d. The peripheral circuit layer 50 may include a third substrate 310, a third shallow element isolation pattern STI3, a third gate insulating film 340, and peripheral circuit gates M×G, and the fourth wiring layer 20d may include third interlayer insulating films 350, third contact plugs 360, third wirings 370, and a fourth bonding pad 440.

The third substrate 310 may have a fifth surface 311 and a sixth surface 313 opposite to the fifth surface 311. The third shallow element isolation pattern STI3 may be disposed in a shallow trench recessed by a specific depth from the fifth surface 311 of the third substrate 310, and the third shallow element isolation pattern STI3 may be adjacent to the fifth surface 311 of the third substrate 310. In some example embodiments, the third shallow element isolation pattern STI3 may define active regions in the third substrate 310.

The peripheral circuit gates M×G may be disposed on the corresponding active regions of the third substrate 310. In some example embodiments, the peripheral circuit gates M×G may be disposed on the fifth surface 311 of the third substrate 310. The third gate insulating film 340 may be disposed between the peripheral circuit gates M×G and the corresponding active regions. Peripheral circuit source/drain regions may be disposed in the corresponding active regions at both sides of each of the peripheral circuit gates M×G.

The third interlayer insulating films 350 may be disposed on the fifth surface 311 of the third substrate 310 to cover the fifth surface 311, the third gate insulating film 340, and the peripheral circuit gates M×G. The third interlayer insulating films 350 may be sequentially stacked on the fifth surface 311 of the third substrate 310. The third contact plugs 360 and the third wirings 370 may be provided in the third interlayer insulating films 350. The fourth bonding pad 440 may be disposed in the uppermost layer among (for example, an uppermost of) the third interlayer insulating films 350.

The first to fourth bonding pads 410, 420, 430, and 440 may electrically connect the first to third structures 100, 200, and 300. In some example embodiments, the first bonding pad 410 and the second bonding pad 420 may be bonded to each other to electrically connect the first structure 100 to the second structure 200. In some example embodiments, the third bonding pad 430 and the fourth bonding pad 440 may be bonded to each other to electrically connect the second structure 200 to the third structure 300.

In some example embodiments, the second structure 200 may be bonded differently from that shown in FIG. 14 by applying upside-down inversion, upside-down-left-right inversion, 180° rotation, etc. For example, the first bonding pad 410 and the third bonding pad 430 may be bonded to each other to electrically connect the first structure 100 to the third structure 200. For example, the second bonding pad 420 and the fourth bonding pad 440 may be bonded to each other to electrically connect the second structure 200 to the third structure 300.

In some example embodiments, the third and fourth bonding pads 430 and 440 may, for example, include copper like the first and second bonding pads 410 and 420. The bonded pads bonded among the first to fourth bonding pads 410, 420, 430, and 440 may be bonded by, for example, a copper-copper bonding technique, and the bonded pads may form a single body without a boundary surface therebetween, but example embodiments are not limited thereto.

In some example embodiments, the bonded films among the first to third interlayer insulating films 150, 250, and 350 may be bonded to each other by, for example, forming covalent bonds. For example, the lowermost layer among the first interlayer insulating films 150 may be bonded to the uppermost layer among the second interlayer insulating films 250. For example, the lowermost layer among the second interlayer insulating films 250 may be bonded to the uppermost layer among the third interlayer insulating films 350.

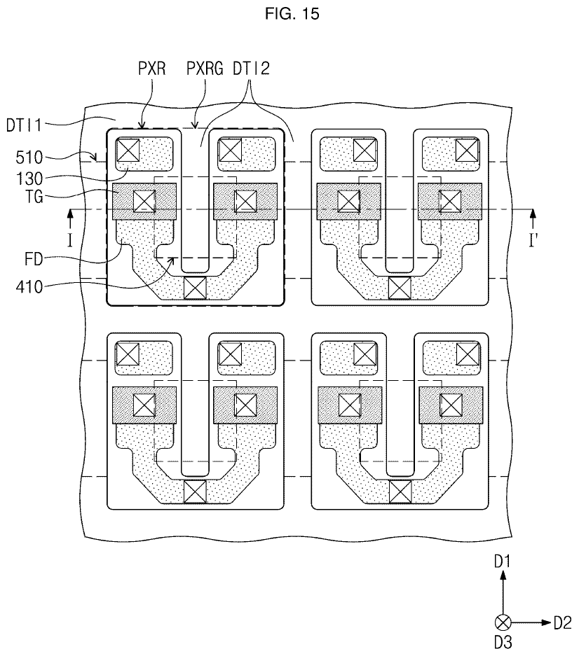

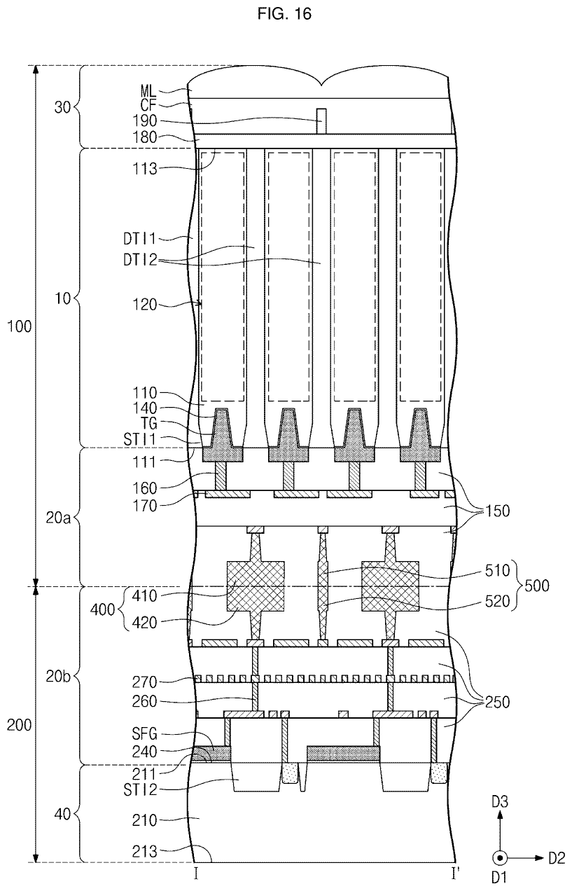

FIG. 15 is a plan view of the image sensor according to some example embodiments. FIG. 16 is a cross-sectional view corresponding to line I-I′ of FIG. 15.

Referring to FIG. 15, each of the pixel region groups PXRG may have a pair of pixel regions PXR. In some example embodiments, the pair of pixel regions PXR may be separated from each other by at least one of a doped isolation region or the second deep element isolation pattern DTI2. For example, the pair of pixel regions PXR may be separated from each other by the second deep element isolation pattern DTI2. In other words, the second deep element isolation pattern DTI2 may be formed between the pair of pixel regions PXR.

The first bonding pad 410 may be provided on the first surface 111 of the first substrate 110 and provided on each of the pixel region groups PXRG. In some example embodiments, the first bonding pad 410 may be provided between the pair of pixel regions PXR, and a portion of the first bonding pad 410 may vertically overlap the second deep element isolation pattern DTI2.

Referring to FIGS. 15 and 16, as previously described, one pixel region group PXRG may include a pair of pixel regions PXR. In addition, one first pickup region 130 and one transfer gate TG may be provided in one pixel region PXR, and one floating diffusion region FD may be provided in the neighboring two pixel regions PXR. In such a case, the floating diffusion region FD may be provided in each of the pixel regions PXR or provided in each of the pair of pixel regions PXR.

Each of the first contact plugs 160 provided in the uppermost layer among the first interlayer insulating films 150 according to some example embodiments may be provided on each of one first pickup region 130, one transfer gate TG, and one floating diffusion region FD.

Each of the second contact plugs 260 provided in the lowermost layer among (for example, lowermost of) the second interlayer insulating films 250 according to some example embodiments may be provided on at least one second pickup region 230 and one source follower gate SFG. The second contact plugs 260 provided on the second pickup region 230 are connected to the second shield conductive patterns 520 in the uppermost layer among the second interlayer insulating films 250 so that the second contact plugs 260 may electrically connect the second pickup region 230 and the second shield conductive patterns 520 along with the second wirings 270. In addition, the second contact plugs 260 provided on the source follower gate SFG are connected to the second bonding pad 420 in the uppermost layer among (for example, uppermost of) the second interlayer insulating films 250 so that the second contact plugs 260 may electrically connect the source follower gate SFG and the second bonding pad 420 along with the second wirings 270.

According to some example embodiments, the chip yield can be improved by forming shield conductive patterns having short line shapes.

Although inventive concepts have been described above with reference to example embodiments, those skilled in the art or those having ordinary skill in the art will be able to understand that example embodiments may be modified and changed in various ways without departing from the spirit and technical scope of inventive concepts as described in the appended claims. For example, it goes without saying that the above-described example embodiments may be combined in various forms to the extent that they are compatible with each other.

Accordingly, the spirit and scope of the inventive concepts should not be limited to the contents described in the detailed descriptions of the specification.

Singular expressions may include plural expressions unless the context clearly indicates otherwise. Terms, such as “include” or “has” may be interpreted as adding features, numbers, steps, operations, components, parts, or combinations thereof described in the specification.

It will be understood that when an element or layer is referred to as being “on”, “connected to”, “coupled to”, “attached to”, or “in contact with” another element or layer, it can be directly on, connected to, coupled to, attached to, or in contact with the other element or layer, or intervening elements or layers may be present. In contrast, when an element is referred to as being “directly on”, “directly connected to”, “directly coupled to”, “directly attached to”, or “in direct contact with” another element or layer, there are no intervening elements or layers present. As used herein, the term “and/or” includes any and all combinations of one or more of the associated listed items.

Spatially relative terms (e.g., “beneath,” “below,” “lower,” “above,” “upper,” and the like) may be used herein for ease of description to describe one element or feature's relationship to another element(s) or feature(s) as illustrated in the figures. It should be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” may encompass both an orientation of above and below. The device may be otherwise oriented (rotated 90 degrees or at other at other orientations) and the spatially relative descriptors used herein interpreted accordingly.

One or more of the elements disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

Any or all of the elements described with reference to FIG. 1 may communicate with any or all other elements described with reference to FIG. 1. For example, any element may engage in one-way and/or two-way and/or broadcast communication with any or all other elements in FIG. 1, to transfer and/or exchange and/or receive information such as but not limited to data and/or commands, such as in a serial and/or parallel manner, via a bus such as a wireless and/or a wired bus (not illustrated). The information may be in encoded various formats, such as in an analog format and/or in a digital format.

What is claimed is:

1. An image sensor, comprising:
a first substrate having a first surface and a second surface opposite to the first surface, the first substrate including a plurality of pixel region groups, each of the pixel region groups including a plurality of pixel regions, the pixel regions being oriented in a first direction and a second direction intersecting the first direction, the first and second directions being parallel to the first surface;
first bonding pads on the first surface of the first substrate and individually on each of the pixel region groups;
first shield conductive patterns on the first surface of the first substrate, the first shield conductive patterns being individually on each of boundaries of the pixel region groups that are parallel to the first direction, the first shield conductive patterns being in matrix form along the first direction and second direction, the first shield conductive patterns of each column of the matrix being physically spaced apart from each other; and
a first pickup region in at least one of the pixel regions of each of the pixel region groups,
wherein each first shield conductive pattern is electrically connected to one of the first pickup regions that is in a corresponding pixel region of the pixel region groups.

2. The image sensor of claim 1, wherein each of the first shield conductive patterns has a bar shape extending in the first direction.

3. The image sensor of claim 1, further comprising:
a floating diffusion region in each of the pixel regions,
wherein each of the first bonding pads is electrically connected to one of the floating diffusion regions that is in a corresponding pixel region of the pixel region groups.

4. The image sensor of claim 1, wherein the first shield conductive patterns are not on boundaries of the pixel region groups that are parallel to the second direction.

5. The image sensor of claim 1, wherein a length of each of the first shield conductive patterns in the first direction is greater than or equal to a width of each of the first bonding pads in the first direction.

6. The image sensor of claim 1, further comprising:
a second substrate having a third surface facing the first surface;
source follower gates on the third surface of the second substrate;
second bonding pads on the third surface of the second substrate;
second shield conductive patterns on the third surface of the second substrate, the second shield conductive patterns being individually on each of the boundaries of the pixel region groups that are parallel to the first direction, the second shield conductive patterns being in matrix form along the first direction and second direction, the second shield conductive patterns of each column of the matrix being physically spaced apart from each other; and
second pickup regions in the second substrate,
wherein each of the second shield conductive patterns is electrically connected to a corresponding pickup region of the second pickup regions.

7. The image sensor of claim 6, wherein the second shield conductive patterns are individually bonded to each of the first shield conductive patterns.

8. The image sensor of claim 6, wherein each of the second shield conductive patterns has a bar shape extending in the first direction.

9. The image sensor of claim 6, wherein each of the second bonding pads is electrically connected to a corresponding source follower gate of the source follower gates.

10. The image sensor of claim 6, wherein the second shield conductive patterns are not on boundaries of the pixel region groups that are parallel to the second direction.

11. The image sensor of claim 6, wherein a length of each of the second shield conductive patterns in the first direction is greater than or equal to a width of each of the second bonding pads in the first direction.

12. The image sensor of claim 6, further comprising:
interlayer insulating films at least partially covering the third surface of the second substrate and the source follower gates,
wherein the second bonding pads and the second shield conductive patterns are in an uppermost one of the interlayer insulating films.

13. An image sensor, comprising:
a first substrate having a first surface and a second surface opposite to the first surface, the first substrate including a plurality of pixel region groups, each of the pixel region groups including a plurality of pixel regions, the pixel regions being oriented in a first direction and a second direction intersecting the first direction, the first and second directions being parallel to the first surface;
first bonding pads on the first surface of the first substrate and individually on each of the pixel region groups;
first shield conductive patterns on the first surface of the first substrate, the first shield conductive patterns being individually on each of boundaries of the pixel region groups that are parallel to the first direction, the first shield conductive patterns being in matrix form along the first direction and second direction, the first shield conductive patterns of each column of the matrix being physically spaced apart from each other;
a first pickup region in at least one of the pixel regions of each of the pixel region groups,
a second substrate having a third surface and a fourth surface, the third surface facing the first surface, the fourth surface opposite to the third surface;
second bonding pads on the third surface of the second substrate;
second shield conductive patterns on the third surface of the second substrate, the second shield conductive patterns being individually bonded to each of the first shield conductive patterns; and
second pickup regions in the second substrate,
wherein each of the first shield conductive patterns is electrically connected to one of the first pickup regions that is in a corresponding pixel region of the pixel region groups, and
each of the second shield conductive patterns is electrically connected to a corresponding pickup region of the second pickup regions.

14. The image sensor of claim 13, wherein each of the first shield conductive patterns and each of the second shield conductive patterns has a bar shape extending in the first direction.

15. The image sensor of claim 13, wherein the first and the second shield conductive patterns are not on boundaries of the pixel region groups that are parallel to the second direction.

16. The image sensor of claim 13, wherein a length of each of the first shield conductive patterns in the first direction is greater than or equal to a width of each of the first bonding pads in the first direction, and
a length of each of the second shield conductive patterns in the first direction is greater than or equal to a width of each of the second bonding pads in the first direction.

17. The image sensor of claim 13, further comprising:
a floating diffusion region in each of the pixel regions; and
source follower gates on the third surface of the second substrate,
wherein each of the first bonding pads is electrically connected to one of the floating diffusion regions that is in a corresponding pixel region of the pixel region groups, and
each of the second bonding pads is electrically connected to a corresponding source follower gate of the source follower gates.

18. The image sensor of claim 17, wherein the first bonding pads and the second bonding pads are individually bonded to each other.

19. The image sensor of claim 13, further comprising
interlayer insulating films at least partially covering the third surface of the second substrate and the source follower gates,
wherein the second bonding pads and the second shield conductive patterns are in an uppermost of the interlayer insulating films.

20. The image sensor of claim 13, further comprising:
third bonding pads on the fourth surface of the second substrate;
a third substrate having a fifth surface that is facing the fourth surface; and
fourth bonding pads on the fifth surface of the third substrate,
wherein the fourth bonding pads are individually bonded to each of the third bonding pads.
